(19) United States
(12) Patent Application Publication
(10) Pub. No.: US 2007/0145989 A1
(43) Pub. Date: Jun. 28, 2007

(54) Probe card with improved transient power delivery

(76) Inventors: Hua Zhu, Campbell, CA (US); Erich A. Chuh, Santa Clara, CA (US); Timothy Swettlen, Tukwila, WA (US)

Correspondence Address: TROP PRUNER & HU, PC, 1616 S. VOSS ROAD, SUITE 750, HOUSTON, TX, 77057-2631, US

(21) Appl. No.: 11/318,660

(22) Filed: Dec. 27, 2005

(51) Int. Cl. G01R 31/02

(52) U.S. Cl. 324/754

(57) ABSTRACT

In high current integrated circuit wafer test applications, a high capacitance density capacitor may be formed in association with a probe card at a position closer to a wafer under test. This reduces the power path impedance, improving transient power delivery of a probe card. That is because now the capacitance is positioned more closely to the wafer under test, reducing path impedance. The capacitance density may be at higher, improving transient power delivery.

### BACKGROUND

Embodiments of this invention relate generally to the electrical testing of silicon wafers and, particularly, to testing wafer products with high current demands such as microprocessors and digital signal processors.

After fabrication, semiconductor wafers are often subjected to electrical tests. These electrical tests involve applying signals and power from an automatic test machine (ATM) through a probe card to the wafer under test.

In order to provide the necessary current draw for high power device testing, decoupling capacitors are often designed on the probe card PCB (Printed Circuit Board) and on the probe card substrate such as a space transformer that is positioned between the probe card PCB and the wafer under test. However, if the electrical path between the decoupling capacitors and the device under test is too long and, therefore, increasingly inductive and resistive, the high current draw of the device may not be met in a timely manner which often results in voltage droop. Given that both the standard methods to reduce high power path impedance and increase decoupling capacitance are approaching their technical limits, if the current is high enough, voltage droop results from the distance between the decoupling capacitors and the device under test.

Thus, better ways are needed to test microprocessors and other high current devices.

### BRIEF DESCRIPTION OF THE DRAWINGS

FIG. 1 is a schematic depiction of one embodiment of the present invention shown in cross-section; and

FIG. 2 is a schematic depiction of another embodiment of the present invention shown in cross-section.

### DETAILED DESCRIPTION

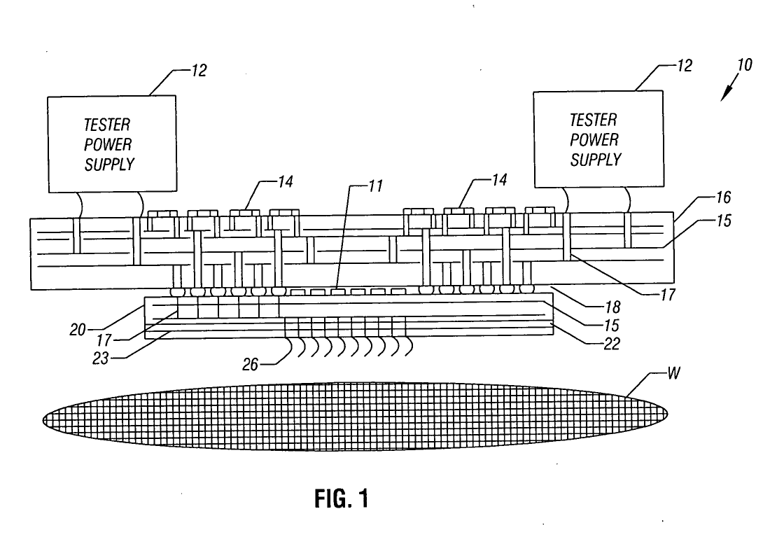

Referring to FIG. 1, tester power supplies 12 may be applied to a probe card 10. One power supply 12 may supply higher currents than the other. The probe card 10 may include a printed circuit board (PCB) 16 and a substrate such as space transformer 20 both having embedded conductive layers 15 for routing the tester power supply and signals to an integrated circuit wafer under test W. A number of decoupling capacitors 14 may be formed on top of the probe card PCB 16. Another group of decoupling capacitors 11 may be formed on top of the space transformer 20, “electrically” closer to wafer under test W.

Vias 17 convey electrical signals and power from the tester power supplies 12 and the decoupling capacitors 14 through the probe card PCB 16. Those vias 17 eventually contact an interposer 18 which, in one embodiment, may be a ball grid array or pin grid array, to mention two examples. The interposer 18 connects electrically the probe card PCB 16 to a space transformer 20. Space transformer vias 17 convey electrical signals and power from the interposer 18 and space transformer capacitors 11 to wafer under test W through probes 26.

The space transformer 20 increases the pitch of the contacts from the lower density pitch used in the probe card to a higher density pitch needed for the wafer under test W. The space transformer 20 may provide for power delivery and input/output routing. The space transformer 20 may also, in some embodiments, provide structural integrity to the probe card 10.

In some embodiments, the space transformer 20 itself may be made of a ceramic material. For example, the space transformer 20 may be a multilayer ceramic (MLC), a multilayer ceramic with multilayer thin films, an aluminum nitride substrate with multiple layer thin films, an organic buildup or a glass ceramic structure, to mention a few examples. The space transformer 20 also includes vias 17 and conductive layers 15.

In one embodiment, the spacer transformer 20 also includes one or more capacitive layers 22 supplied thereon. In some embodiments, two or more layers of conductive material may be separated by a dielectric such as a thin film layer or a ceramic layer. Thus, in some embodiments, a high capacitance density capacitor may be formed on the probe side of the space transformer 20 so as to position the capacitor as close as possible to the wafer under test W.

The capacitor 22 and its plates 23 provide additional decoupling capacitance. The decoupling capacitance supplied by the capacitor 22 formed in the space transformer 20 substrate may be more effective than that provided by the decoupling capacitors 14 on top of the probe card PCB 16 or the decoupling capacitors 11 on top of the space transformer 20. This is because the closer the high capacitance can be positioned to the device under test, the better it decouples the power delivery and provides instant power to the wafer under test W. This is especially important with high current wafers under test, such as with microprocessors or digital signal processors. The probes 26 then extend downwardly from the space transformer 20 to make appropriate contacts on the wafer under test W.

In some embodiments, the capacitor 22 may have a relatively high capacitance density. By high capacitance density, it is intended to refer to a capacitance density of, for example, at least about 1.0 microfarads per square centimeter. The high capacitance density in capacitor 22 may be achieved by applying multiple capacitance layers and applying high dielectric material in between each layer. Besides the high capacitance density, the vias and conductive plates in capacitor 22 may also provide very low effective inductance and resistance, reducing the effective impedance of the probe card W power paths.

As a result of the power path impedance reduction from positioning the capacitance closer to the wafer under test W, better transient power delivery is achieved and voltage droop may be substantially reduced in some embodiments.

In accordance with another embodiment of the present invention, instead of applying the capacitor 22 to the probe side of the space transformer 20, the capacitance may actually be embedded within the layers of the space transformer 20. For example, this may be advantageous in situations in which the space transformer is made of a dielectric material which is highly effective in increasing capacitance density. Examples of such material include ceramic and organic build up materials.

The conductive layers that form the capacitor 22 may be readily connected to power and ground connections, which are already available within the space transformer 20.

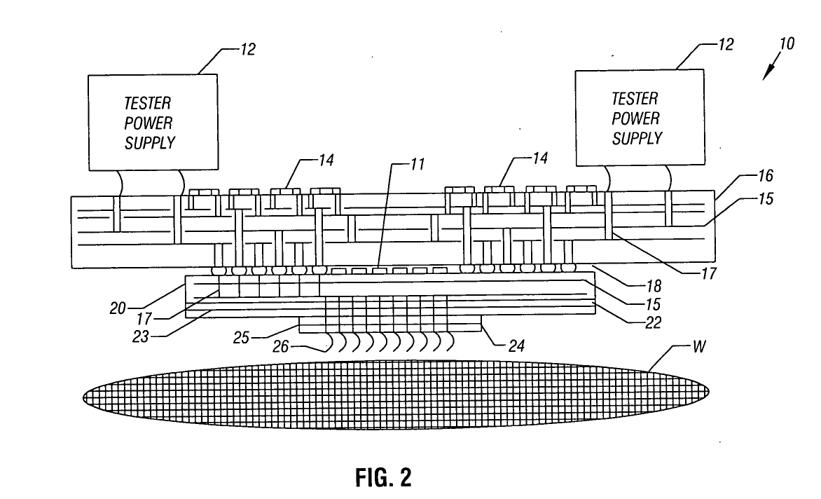

Referring to FIG. 2, in accordance with another embodiment of the present invention, a secondary substrate 24 is used below the space transformer 20. In such case, the capacitor 22 is applied to the probe side of the secondary substrate 24, instead of to the space transformer 20. This places the capacitance as close as possible to the wafer under test W. Thus, in cases where the secondary substrate 24 is utilized, the capacitor may be placed even closer to the wafer under test W by virtue of placing it on the probe side of the secondary substrate 24.

In such case, the capacitive layer 25 may, again, be connected to power and ground which already exist within the secondary substrate 24. In some embodiments, the capacitor may be embedded within the secondary substrate 24 and, in other embodiments, it may be placed on the face of the secondary substrate facing the device under test.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations there from. It is intended that the appended claims cover all such modifications and variations as fall within the true spirit and scope of this present invention.

What is claimed is:

1. A method comprising:
forming a decoupling capacitor between a probe card and a wafer under test.

2. The method of claim 1 including forming said capacitor in association with a space transformer.

3. The method of claim 2 including forming said capacitor on the probe side of said space transformer.

4. The method of claim 1 including forming said capacitor on a secondary substrate.

5. The method of claim 4 including forming said capacitor on the probe side of said secondary substrate.

6. The method of claim 1 including forming said capacitor having a capacitance density of at least 1.0 microfarads per square centimeter.

7. An electrical testing device comprising:
a probe card;
a structure secured to said probe card;
probes extending from said structure; and
a capacitor formed in association with said structure.

8. The device of claim 7 wherein said structure includes a space transformer, said capacitor formed in connection with said space transformer.

9. The device of claim 8 wherein said capacitance is formed on the probe side of said space transformer.

10. The device of claim 7 wherein said structure includes a secondary substrate, the capacitor formed in association with said secondary substrate.

11. The device of claim 10 wherein the capacitor is formed on the probe side of said secondary substrate.

12. The device of claim 7 wherein said capacitor has a capacitance density of at least 1.0 microfarads per square centimeter.

13. A method comprising:
securing a structure to the probe side of a probe card; and
forming a capacitor having a capacitance density of at least 1.0 microfarads per square centimeter on said structure.

14. The method of claim 13 including forming a structure including a space transformer.

15. The method of claim 14 including depositing said capacitor on the probe side of said space transformer.

16. The method of claim 13 including forming a structure including a space transformer and a secondary substrate.

17. The method of claim 16 including forming a capacitor by depositing said capacitor on the probe side of said secondary substrate.

18. A probe card comprising:
a plurality of probes; and
a decoupling capacitor having a capacitance density of greater than 1.0 microfarads per square centimeter.

19. The card of claim 18, said card having a space transformer having a probe side, wherein said capacitor is formed on the probe side of a space transformer.

20. The card of claim 18, said card having a secondary substrate, having a probe side and said capacitor formed on said secondary substrate.

21. The card of claim 20 including forming said capacitor on the probe side of said secondary substrate.
